(19) United States
(12) Patent Application Publication
(10) Pub. No.: US 2025/0364918 A1
(43) Pub. Date: Nov. 27, 2025

(54) RECTIFIER MODULE

(71) Applicant: Delta Electronics (Shanghai) Co., Ltd., Shanghai (CN)

(72) Inventors: Kai Dong, Shanghai (CN); Kunpeng Wang, Shanghai (CN); Weihan Chen, Shanghai (CN)

(21) Appl. No.: 19/190,009

(22) Filed: Apr. 25, 2025

(30) Foreign Application Priority Data
May 23, 2024 (CN) 202421144956.4

(51) Int. Cl. H02M 7/00; H02M 1/14; H02M 1/44; H05K 1/14; H05K 1/18

(52) U.S. Cl. CPC H02M 7/003; H02M 1/14; H02M 1/44; H05K 1/141; H05K 1/181; H05K 2201/047; H05K 2201/10015; H05K 2201/1003; H05K 2201/1006

(57) ABSTRACT

A rectifier module is disposed on a mainboard. The rectifier module includes a first circuit board, a second circuit board, a transformer, a third circuit board and a plurality of output filter capacitors. The first circuit board and the second circuit board are inserted into the mainboard. The first circuit board and the second circuit board are opposite to each other. The transformer is arranged between and connected to the first circuit board and the second circuit board. A first side of the third circuit board is connected to the first circuit board. A second side of the third circuit board is connected to the second circuit board. The plurality of output filter capacitors are disposed on the third circuit board. The rectifier module is electrically connected to the mainboard via a positive connection part and a negative connection part.

### CROSS-REFERENCE TO RELATED APPLICATION

This application claims priority to China Patent Application No. 202421144956.4, filed on May 23, 2024, the entire contents of which are incorporated herein by reference for all purposes.

### FIELD OF THE INVENTION

The present disclosure relates to the field of a power electronics technology, and more particularly to a rectifier module.

### BACKGROUND OF THE INVENTION

Nowadays, rectifier modules are widely used in power circuits. However, due to the increasing requirements for dynamic performance and output ripple, the conventional rectifier modules are gradually becoming unable to meet the latest design specifications.

The conventional rectifier module is disposed on a mainboard. In addition, the rectifier module includes a transformer and two circuit boards. The two circuit boards are disposed on both sides of the transformer. The two circuit boards are connected to each other through a positive connection part and a negative connection part, both of which are made of copper sheets. In addition, the two circuit boards are inserted into the mainboard.

In the conventional rectifier modules, the filtering elements are usually disposed on the circuit boards on both sides of the transformer. In addition, other electronic components such as power devices also need to be disposed on the circuit boards on both sides of the transformer. Consequently, there are limited locations available for mounting the filtering elements in the conventional rectifier modules. In other words, the dynamic response of the conventional rectifier modules is not satisfactory enough, and the output ripple characteristics are poor.

Therefore, it is important to provide a rectifier module to overcome the problems of the conventional technologies. It should be noted that the information disclosed in the above technical contents is only used to enhance the understanding of the background of the present disclosure. In other words, the above technical contents may include information that does not constitute prior art technology known to ordinary technicians in this field.

### SUMMARY OF THE INVENTION

The present disclosure provides a rectifier module with fast dynamic response characteristics and good output ripple characteristics

In accordance with an aspect of the present disclosure, a rectifier module is provided. The rectifier module is disposed on a mainboard. The rectifier module includes a first circuit board, a second circuit board, a transformer, a third circuit board and a plurality of output filter capacitors. The first circuit board is inserted into the mainboard. The second circuit board is inserted into the mainboard and positioned opposite to the first circuit board. The transformer is arranged between the first circuit board and the second circuit board and is connected to both. The third circuit board is located adjacent to the transformer. A first side of the third circuit board is connected to a first side of the first circuit board. A second side of the third circuit board is connected to a first side of the second circuit board. The plurality of output filter capacitors are disposed on the third circuit board. The rectifier module is electrically connected to the mainboard via a positive connection part and a negative connection part.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1A is a schematic perspective view illustrating the structure of a rectifier module according to a first embodiment of the present disclosure;

FIG. 1B is a schematic exploded view illustrating the rectifier module shown in FIG. 1A;

FIG. 2A is a schematic perspective view illustrating the structure of a rectifier module according to a second embodiment of the present disclosure;

FIG. 2B is a schematic exploded view illustrating the rectifier module shown in FIG. 2A;

FIG. 3A is a schematic perspective view illustrating the structure of a rectifier module according to a third embodiment of the present disclosure;

FIG. 3B is a schematic exploded view illustrating the rectifier module shown in FIG. 3A;

FIG. 4A is a schematic perspective view illustrating the structure of a rectifier module according to a fourth embodiment of the present disclosure;

FIG. 4B is a schematic exploded view illustrating the rectifier module shown in FIG. 4A;

FIG. 5A is a schematic perspective view illustrating the structure of a rectifier module according to a fifth embodiment of the present disclosure;

FIG. 5B is a schematic exploded view illustrating the rectifier module shown in FIG. 5A;

FIG. 6A is a schematic perspective view illustrating the structure of a rectifier module according to a sixth embodiment of the present disclosure;

FIG. 6B is a schematic exploded view illustrating the rectifier module shown in FIG. 6A;

FIG. 7A is a schematic perspective view illustrating the structure of a rectifier module according to a seventh embodiment of the present disclosure; and

FIG. 7B is a schematic exploded view illustrating the rectifier module shown in FIG. 7A.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

Unless otherwise expressly specified or limited, the term “connected” and the term “connection” should be understood in a broad sense. For example, it can be a fixed connection, a detachable connection, or an integral connection. In addition, it can be a mechanical connection or an electrical connection. Alternatively, it can be a direct connection or an indirect connection through an intermediate medium.

The concepts of the present disclosure will be illustrated with reference to some embodiments in conjunction with accompanying drawings. In the absence of conflict, the following embodiments and the features in the following embodiments may be combined with each other, and the same or similar concepts or processes may not be described in detail in some embodiments.

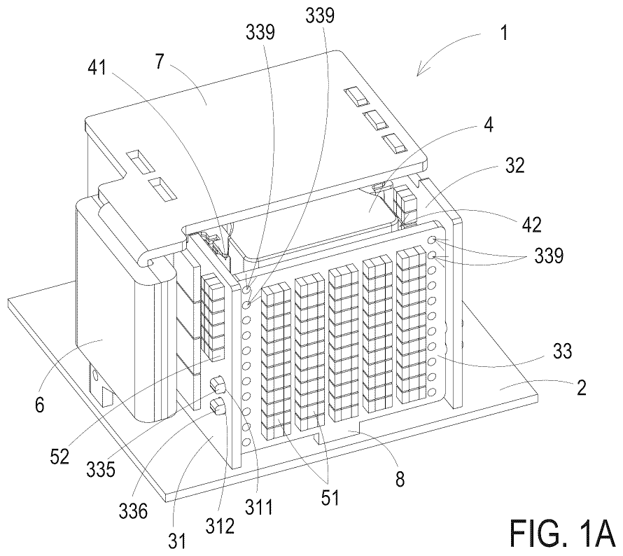

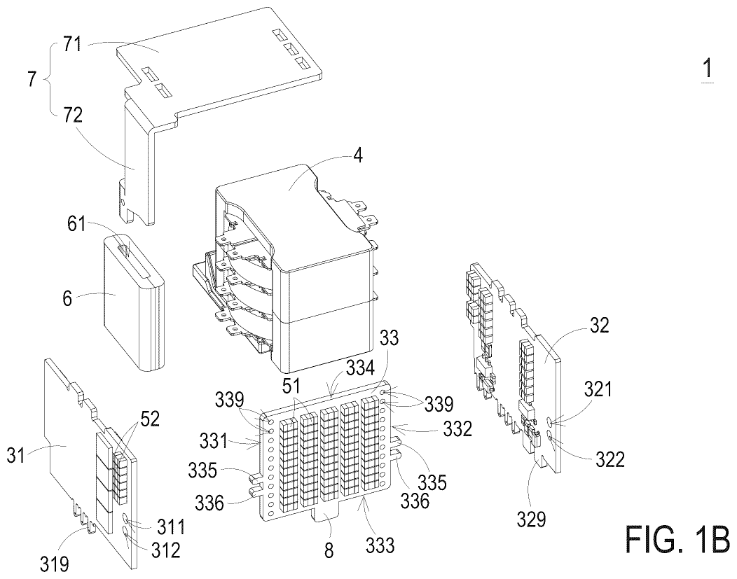

FIG. 1A is a schematic perspective view illustrating the structure of a rectifier module according to a first embodiment of the present disclosure. FIG. 1B is a schematic exploded view illustrating the rectifier module shown in FIG. 1A.

As shown in FIGS. 1A and 1B, the rectifier module 1 is disposed on a mainboard 2. In addition, the rectifier module 1 includes a first circuit board 31, a second circuit board 32, a third circuit board 33, a transformer 4, a plurality of output filter capacitors 51, a magnetic core 6, a positive connection part 7 and a negative connection part 8.

The first circuit board 31 is inserted into the mainboard 2. The second circuit board 32 is inserted into the mainboard 2. In addition, the first circuit board 31 and the second circuit board 32 are opposite to each other.

The transformer 4 is arranged between the first circuit board 31 and the second circuit board 32. A first gap 41 is formed between a first side of the transformer 4 and the first circuit board 31. A second gap 42 is formed between a second side of the transformer 4 and the second circuit board 32. The transformer 4 is connected to the first circuit board 31 and the second circuit board 32.

The third circuit board 33 is located adjacent to the transformer 4. However, the third circuit board 33 is not in contact with the transformer 4. The third circuit board 33 is arranged between the first circuit board 31 and the second circuit board 32. That is, the first circuit board 31, the third circuit board 33 and the second circuit board 32 surround the transformer 4 in sequence. The third circuit board 33 includes a first side 331, a second side 332, a third side 333 and a fourth side 334. The first side 331 and the second side 332 are opposite to each other. The third side 333 and the fourth side 334 are opposite to each other. The first side 331 of the third circuit board 33 is connected to the first side of the first circuit board 31. The second side 332 of the third circuit board 33 is connected to the first side of the second circuit board 32.

In an embodiment, the plurality of output filter capacitors 51 are disposed on a surface of the third circuit board 33 away from the transformer 4. In a variant example, the plurality of output filter capacitors 51 are disposed on a surface of the third circuit board 33 close to the transformer 4. In another variant example, the plurality of output filter capacitors 51 are disposed on both surfaces of the first circuit board 31 and the second circuit board 32. In addition, the plurality of output filter capacitors 51 are electrically connected between the positive connection part 7 and the negative connection part 8. The magnetic core 6 is disposed on a surface of the first circuit board 31 away from the transformer 4. In addition, the magnetic core 6 includes a hollow portion 61.

The rectifier module 1 is connected to the mainboard 2 via the positive connection part 7 and the negative connection part 8. In an embodiment, the positive connection part 7 is made of a copper sheet. Moreover, the positive connection part 7 includes a first positive connection segment 71 and a second positive connection segment 72, and the first positive connection segment 71 and the second positive connection segment 72 are connected to each other. It is noted that the shape of the positive connection part 7 is not restricted. For example, in an embodiment, the positive connection part 7 has an L-shaped structure. The first circuit board 31 and the second circuit board 32 are connected to the first positive connection segment 71. For example, the first circuit board 31 and the second circuit board 32 are inserted into the first positive connection part 71. The second positive connection segment 72 passes through a hollow portion 61 of the magnetic core 6. Consequently, the second positive connection segment 72 and the magnetic core 6 collectively form as an inductor. In addition, the second positive connection segment 72 is inserted into the mainboard 2. In other words, the first circuit board 31 is arranged between the second positive connection segment 72 and the transformer 4.

In some embodiments, the position of the first positive connection segment 71 may be varied according to the practical requirements. For example, in a variant example, the first positive connection segment 71 and the third circuit board 33 are located on opposite sides of the transformer 4. That is, the transformer 4 is arranged between the first positive connection segment 71 and the third circuit board 33. In some embodiments, the position of the second positive connection segment 72 may be varied according to the practical requirements. For example, in a variant example, the second positive connection segment 72 and the third circuit board 33 are located on opposite sides of the transformer 4. That is, the transformer 4 is arranged between the second positive connection segment 72 and the third circuit board 33. In this embodiment, the negative connection part 8 is a portion of the third circuit board 33. That is, the negative connection part 8 and the third circuit board 33 are integrally formed into a one-piece structure. The negative connection portion 8 is located on the third side 333 of the third circuit board 33 and inserted into the mainboard 2. In some embodiments, the position of the third circuit board 33 may be varied according to the practical requirements. That is, one possible position of the third circuit board 33 is shown in FIG. 1A. However, the third circuit board 33 may be located beside another side of the transformer 4.

As mentioned above, the rectifier module 1 includes three circuit boards, i.e., the first circuit board 31, the second circuit board 32 and the third circuit board 33. The transformer 4 is arranged between the first circuit board 31 and the second circuit board 32. The third circuit board 33 is located adjacent to the transformer 4. In addition, two sides of the third circuit board 33 are respectively connected to the first circuit board 31 and the second circuit board 32, and the plurality of output filter capacitors 51 can be disposed on any circuit board. In the conventional rectifier module, the filter element can only be disposed on two opposite circuit boards. In contrast, the output filter capacitor 51 in the rectifier module 1 of the present disclosure can also be disposed on the third circuit board 33. In other words, the rectifier module 1 of the present disclosure may be provided with a larger number of output filter capacitors 51. Consequently, the space utilization of the rectifier module is effectively increased, the output ripple is optimized, and the dynamic performance is improved.

Please refer to FIGS. 1A and 1B again. In an embodiment, the first circuit board 31 includes at least one first through-hole 311 and at least one second through-hole 312. The first through-hole 311 of the first circuit board 31 is the first potential terminal of the first circuit board 31. The second through-hole 312 of the first circuit board 31 is the second potential terminal of the first circuit board 31. The first through-hole 311 and the second through-hole 312 are both formed on the side of the first circuit board 31 closest to the third circuit board 33. The second circuit board 32 includes at least one first through-hole 321 and at least one second through-hole 322. The first through-hole 321 of the second circuit board 32 is the first potential terminal of the second circuit board 32. The second through-hole 322 of the second circuit board 32 is the second potential terminal of the second circuit board 32. The first through-hole 321 and the second through-hole 322 of the second circuit board 32 are both formed on the side of the second circuit board 32 closest to the third circuit board 33.

The third circuit board 33 includes at least two first insertion parts 335 and at least two second insertion parts 336. Each of the first insertion parts 335 of the third circuit board 33 is the first potential terminal of the third circuit board 33. The first insertion part 335 of the third circuit board 33 adjacent to the first circuit board 31 is inserted into the first through-hole 311 of the first circuit board 31. The first insertion part 335 of the third circuit board 33 adjacent to the second circuit board 32 is inserted into the first through-hole 321 of the second circuit board 32. Each of the second insertion parts 336 of the third circuit board 33 is a second potential terminal of the third circuit board 33. The second insertion part 336 of the third circuit board 33 adjacent to the first circuit board 31 is inserted into the second through-hole 312 of the first circuit board 31. The second insertion part 336 of the third circuit board 33 adjacent to the second circuit board 32 is inserted into the second through-hole 322 of the second circuit board 32.

As mentioned above, the first potential terminals of the third circuit board 33 are electrically connected to the first potential terminal of the first circuit board 31 and the first potential terminal of the second circuit board 32, and the second potential terminals of the third circuit board 33 are electrically connected to the second potential terminal of the second circuit board 31 and the second potential terminal of the second circuit board 32. In addition, the potential of the first insertion part 335 of the third circuit board 33 is identical to the potential of the first terminal of the second positive connection segment 72 (i.e., the terminal connected to the first positive connection segment 71) or the potential of the second terminal of the second positive connection segment 72 (i.e., the terminal connected to the mainboard 2), and the potential of the second insertion part 336 of the third circuit board 33 is identical to the potential of the negative connection part 8.

Generally, the filtering circuit following rectification is typically a CLC (capacitor-inductor-capacitor) filtering circuit. That is, signals are sequentially processed through the first output filter capacitor, the inductor and the second output filter capacitor. Generally, the capacitance of the first output filter capacitor is smaller than the capacitance of the second output filter capacitor. In case that the potential of the first insertion part 335 of the third circuit board 33 is identical to the potential of the first terminal of the second positive connection segment 72 (i.e., the terminal connected to the first positive connection segment 71), the output filter capacitors 51 on the third circuit board 33 serve as the first output filter capacitor, and the output signal from the transformer 4 is firstly filtered by the first output filter capacitor 51, then filtered by the inductor formed by the magnetic core 6 and the second positive connection segment 72, and finally filtered by the second output filter capacitor located at a different position. In case that the potential of the first insertion part 335 of the third circuit board 33 is identical to the potential of the second terminal of the second positive connection segment 72 (i.e., the terminal connected to the mainboard 2), the output filter capacitors 51 on the third circuit board 33 serve as the second output filter capacitor, and the output signal from the transformer 4 is first filtered by the first output filter capacitor located at a different position, then filtered by the inductor, and finally filtered by the output filter capacitors 51. Of course, some of the output filter capacitors 51 on the third circuit board 33 may serve as the first output filter capacitor, while others may function as the second output filter capacitor. Under this circumstance, the third circuit board 33 is additionally equipped with insertion parts to connect to the corresponding potential terminals of the first circuit board 31 and the second circuit board 32. If the filtering performance of the first and second output filter capacitors is sufficient, the magnetic core 6 may be omitted. That is, the filtering function is achieved exclusively through the first and second output filter capacitors.

Please refer to FIGS. 1A and 1B again. In an embodiment, the third circuit board 33 of the rectifier module 1 includes a plurality of ventilation holes 339. The plurality of ventilation holes 339 penetrate the third circuit board 33. It is noted that the positions of the ventilation holes 339 are not restricted. In an embodiment of FIG. 1B, some of the ventilation holes 339 are sequentially arranged on the third circuit board 33 and located adjacent to the first side of the first circuit board 31, and a first airflow channel is defined by the ventilation holes 339 adjacent to the first circuit board 31 and the first gap 41. In addition, the other ventilation holes 339 are sequentially arranged on the third circuit board 33 and located adjacent to the first side of the second circuit board 32, and a second airflow channel is defined by the ventilation holes 339 adjacent to the second circuit board 32 and the second gap 42. The heat generated by the transformer 4 can be transferred to the external environment outside the rectifier module 1 via the airflow channels, significantly improving the heat dissipation efficiency.

In an embodiment, the first circuit board 31 includes at least one first output pin 319. The first circuit board 31 is inserted into the mainboard 2 via the at least one first output pin 319. Consequently, the electrical connection between the first circuit board 31 and the mainboard 2 is established. The second circuit board 32 includes at least one second output pin 329. The second circuit board 32 is inserted into the mainboard 2 via the at least one second output pin 329. Consequently, the electrical connection between the second circuit board 32 and the mainboard 2 is established. In an embodiment, the rectifier module 1 further includes a plurality of rectifier switches 52. Some rectifier switches 52 are disposed on the side of the first circuit board 31 away from the transformer 4, others are disposed on the side of the second circuit board 32 away from the transformer 4.

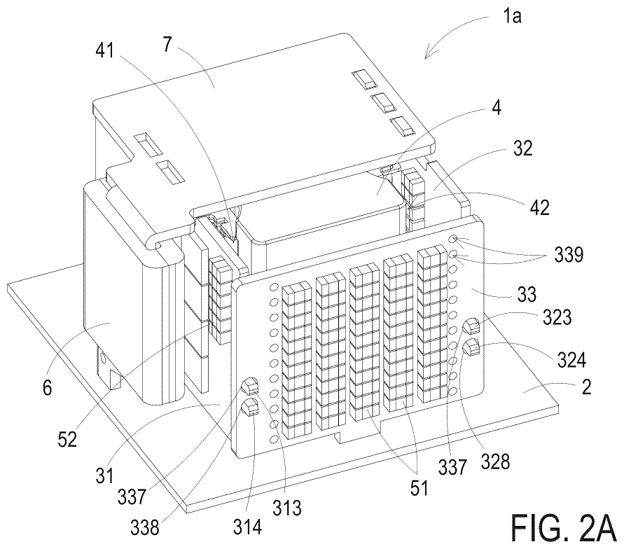

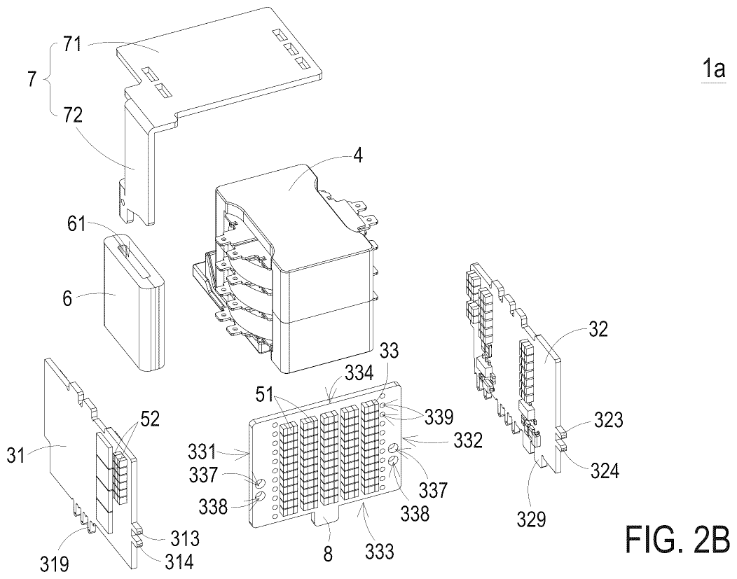

In some embodiments, the positions of the through-holes and the insertion parts may be varied according to the practical requirements. FIG. 2A is a schematic perspective view illustrating the structure of a rectifier module according to a second embodiment of the present disclosure. FIG. 2B is a schematic exploded view illustrating the rectifier module shown in FIG. 2A.

In the rectifier module 1a of the first embodiment, the third circuit board 33 includes at least two first through-holes 337 and at least two second through-holes 338. Each of the first through-holes 337 of the third circuit board 33 is the first potential terminal of the third circuit board 33. In addition, at least one first through-hole 337 is located adjacent to the first circuit board 31, and at least one first through-hole 337 is located adjacent to the second circuit board 32. Each of the second through-holes 338 of the third circuit board 33 is the second potential terminal of the third circuit board 33. In addition, at least one second through-hole 338 is located adjacent to the first circuit board 31, and at least one second through-hole 338 is located adjacent to the second circuit board 32.

The first circuit board 31 includes at least one first insertion part 313 and at least one second insertion part 314. The first insertion part 313 of the first circuit board 31 is the first potential terminal of the first circuit board 31. The second insertion part 314 of the first circuit board 31 is the second potential terminal of the first circuit board 31. At least one first insertion part 313 of the first circuit board 31 is inserted into the corresponding first through-hole 337 of the third circuit board 33 adjacent to the first circuit board 31. At least one second insertion part 314 of the first circuit board 31 is inserted into the corresponding second through-hole 338 of the third circuit board 33 adjacent to the first circuit board 31.

The second circuit board 32 includes at least one first insertion part 323 and at least one second insertion part 324. The first insertion part 323 of the second circuit board 32 is a first potential terminal of the second circuit board 32. The second insertion part 324 of the second circuit board 32 is a second potential terminal of the second circuit board 32. At least one first insertion part 323 of the second circuit board 32 is inserted into the corresponding first through-hole 337 of the third circuit board 33 adjacent to the second circuit board 32. At least one second insertion part 324 of the second circuit board 32 is inserted into the corresponding second through-hole 338 of the third circuit board 33 adjacent to the second circuit board 32.

In this embodiment, the potential of the first insertion part 313 of the first circuit board 31 is identical to the potential of the first terminal of the second positive connection segment 72 (i.e., the terminal connected to the first positive connection segment 71) or the potential of the second terminal of the second positive connection segment 72 (i.e., the terminal connected to the mainboard 2), and the potential of the second insertion part 314 of the first circuit board 31 is identical to the potential of the negative connection part 8. Similarly, the potential of the first insertion part 323 of the second circuit board 32 is identical to the potential of the first terminal of the second positive connection segment 72 or the potential of the second terminal of the second positive connection segment 72, and the potential of the second insertion part 324 of the second circuit board 32 is identical to the potential of the negative connection part 8.

In case that the potential of the first insertion part 313 of the first circuit board 31 and the potential of the first insertion part 323 of the second circuit board 32 are both identical to the potential of the first terminal of the second positive connection segment 72 (i.e., the terminal connected to the first positive connection segment 71), the output filter capacitors 51 on the third circuit board 33 serve as the first output filter capacitor, and the output signal from the transformer 4 is firstly filtered by the first output filter capacitor 51, then filtered by the inductor formed by the magnetic core 6 and the second positive connection segment 72, and finally filtered by the second output filter capacitor located at a different position. In case that the potential of the first insertion part 313 of the first circuit board 31 and the potential of the first insertion part 323 of the second circuit board 32 are both identical to the potential of the second terminal of the second positive connection segment 72 (i.e., the terminal connected to the mainboard 2), the output filter capacitors 51 on the third circuit board 33 serve as the second output filter capacitor, and the output signal from the transformer 4 is firstly filtered by the first output filter capacitor located at a different position, then filtered by the inductor, and finally filtered by the output filter capacitors 51. Of course, some of the output filter capacitors on the third circuit board 33 may serve as the first output filter capacitor, while others may function as the second output filter capacitor. Under this circumstance, each of the first circuit board 31 and the second circuit board 32 is additionally equipped with insertion parts to connect to the corresponding potential terminals of the third circuit board 33. If the filtering performance of the first and second output filter capacitors is sufficient, the magnetic core 6 may be omitted. That is, the filtering function is achieved exclusively through the first and second output filter capacitors.

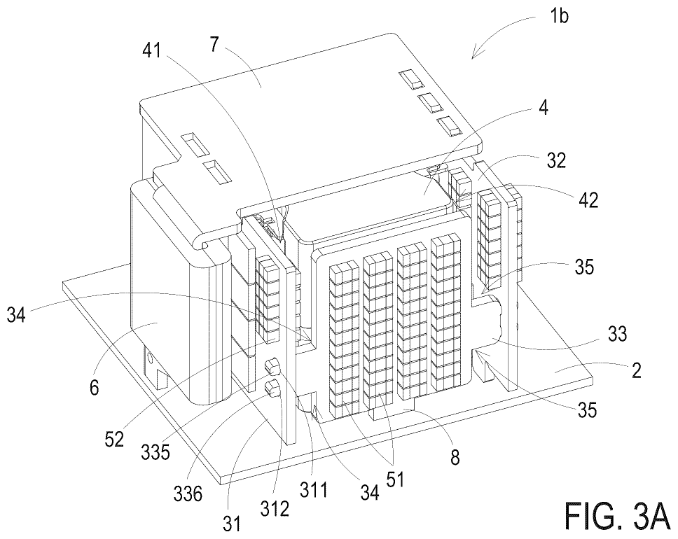

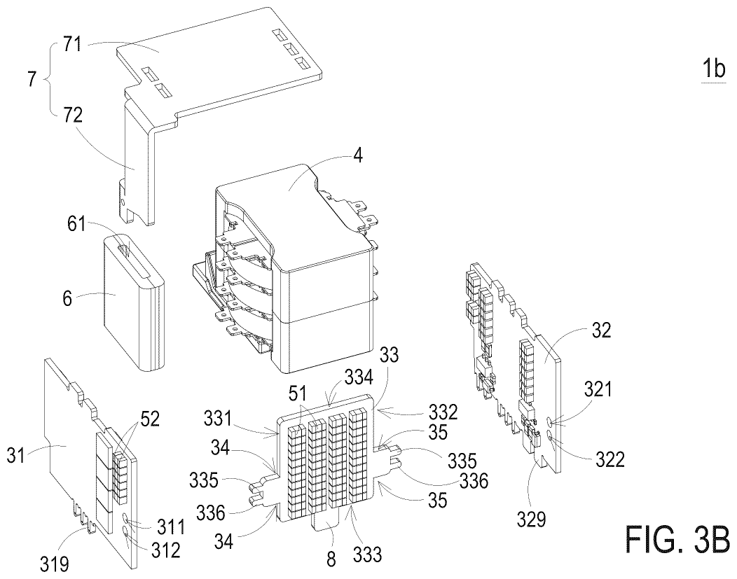

In some embodiments, the rectifier module further includes concave structures to enhance heat dissipation capability. FIG. 3A is a schematic perspective view illustrating the structure of a rectifier module according to a third embodiment of the present disclosure. FIG. 3B is a schematic exploded view illustrating the rectifier module shown in FIG. 3A. As mentioned above, the third circuit board 33 in the rectifier module 1 of the first embodiment shown in FIGS. 1A and 1B includes a plurality of ventilation holes 339. In this embodiment, the ventilation holes may be omitted.

In the rectifier module 1b of this embodiment, a first distance is defined between the first side 331 of at least a portion of the third circuit board 33 and the first circuit board 31. Consequently, a first concave structure 34 is formed between the at least a portion of the third circuit board 33 and the first circuit board 31. The first concave structure 34 and the first gap 41 constitute the first airflow channel. Similarly, a second distance is defined between the second side 332 of at least a portion of the third circuit board 33 and the second circuit board 32. Consequently, a second concave structure 35 is formed between the at least a portion of the third circuit board 33 and the second circuit board 32. The second concave structure 35 and the second gap 42 constitute the second airflow channel.

As mentioned above, the first airflow channel is defined by the first concave structure 34 and the first gap 41, and the second airflow channel is defined by the second concave structure 35 and the second gap 42. The heat generated by the transformer 4 can be transferred to the external environment outside the rectifier module 1b via the airflow channels, significantly improving the heat dissipation efficiency. It is noted that the number of the first concave structure 34 and the second concave structure 35 may be determined according to the practical requirement.

It is noted that numerous modifications and alterations may be made while retaining the teachings of the disclosure. For example, in a variant example, the rectifier module includes concave structures and ventilation holes for heat dissipation.

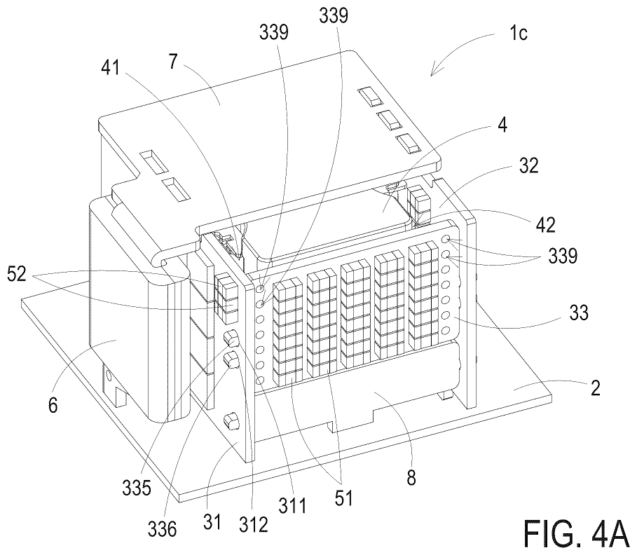

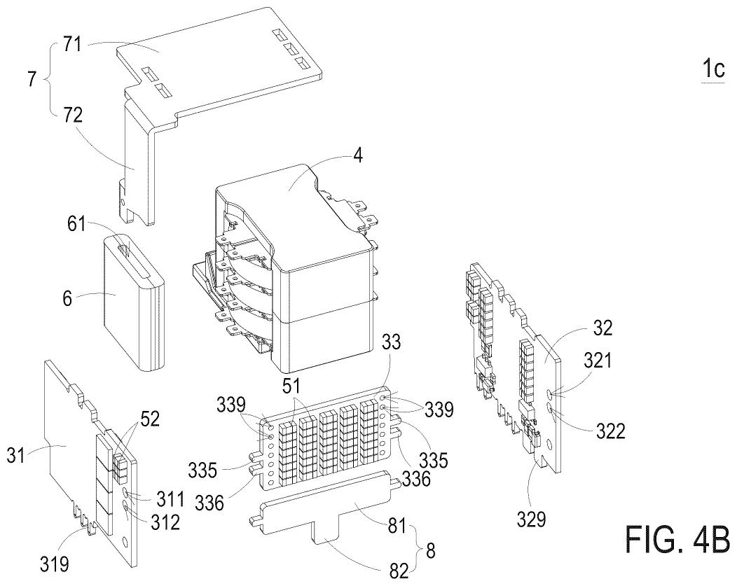

In the above embodiments, the negative connection part of the rectifier module is a partial structure of a circuit board. In some embodiments, the negative connection part of the rectifier module is an additional copper sheet. FIG. 4A is a schematic perspective view illustrating the structure of a rectifier module according to a fourth embodiment of the present disclosure. FIG. 4B is a schematic exploded view illustrating the rectifier module shown in FIG. 4A. Comparing with the rectifier module 1 shown in FIGS. 1A and 1B, the negative connection part 8 in the rectifier module 1c of this embodiment is arranged between the third circuit board 33 and the mainboard 2. The negative connection part 8 includes a first negative connection segment 81 and a second negative connection segment 82. The first negative connection segment 81 and the second negative connection segment 82 are connected to each other. The two terminals of the first negative connection segment 81 are respectively connected to the first circuit board 31 and the second circuit board 32. The second negative connection segment 82 extends from the first negative connection segment 81 toward the direction toward the mainboard 2. The negative connection part 8 is inserted into the mainboard 2 through the second negative connection segment 82. In this embodiment, the third circuit board 33 is arranged between the transformer 4 and the negative connection part 8. In variant example, the negative connection part 8 is arranged between the third circuit board 33 and the transformer 4. In another example, the negative connection part 8 and the third circuit board 33 are coplanar with each other.

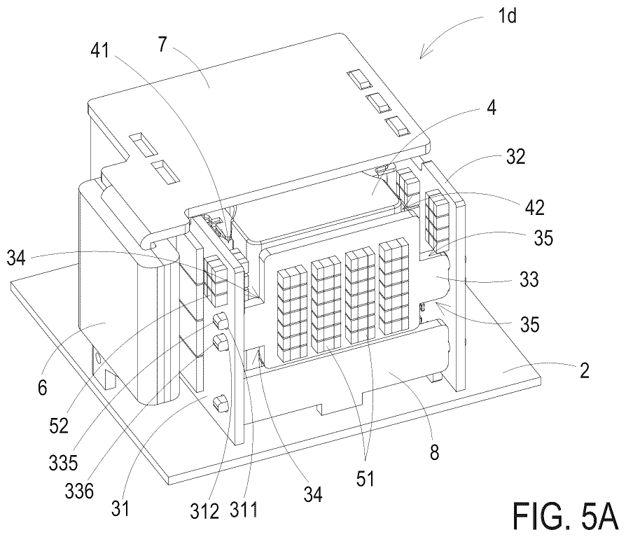

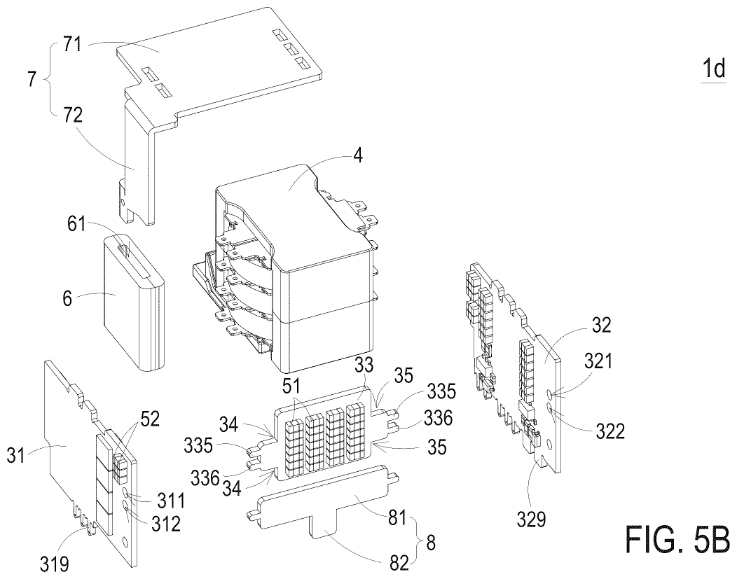

Of course, the rectifier module 1c of the fourth embodiment may further include concave structures to enhance the heat dissipation capability. FIG. 5A is a schematic perspective view illustrating the structure of a rectifier module according to a fifth embodiment of the present disclosure. FIG. 5B is a schematic exploded view illustrating the rectifier module shown in FIG. 5A. As mentioned above, the third circuit board 33 in the rectifier module 1c shown in FIGS. 4A and 4B includes a plurality of ventilation holes 339. In this embodiment, the ventilation holes may be omitted.

In the rectifier module 1d of this embodiment, a first distance is defined between the first side 331 of at least a portion of the third circuit board 33 and the first circuit board 31. Consequently, a first concave structure 34 is formed between the at least a portion of the third circuit board 33 and the first circuit board 31. The first concave structure 34 and the first gap 41 constitute the first airflow channel. Similarly, a second distance is defined between the second side 332 of at least a portion of the third circuit board 33 and the second circuit board 32. Consequently, a second concave structure 35 is formed between the at least a portion of the third circuit board 33 and the second circuit board 32. The second concave structure 35 and the second gap 42 constitute the second airflow channel.

As mentioned above, the first airflow channel is defined by the first concave structure 34 and the first gap 41, and the second airflow channel is defined by the second concave structure 35 and the second gap 42. The heat generated by the transformer 4 can be transferred to the external environment outside the rectifier module 1d via the airflow channels, significantly improving the heat dissipation efficiency.

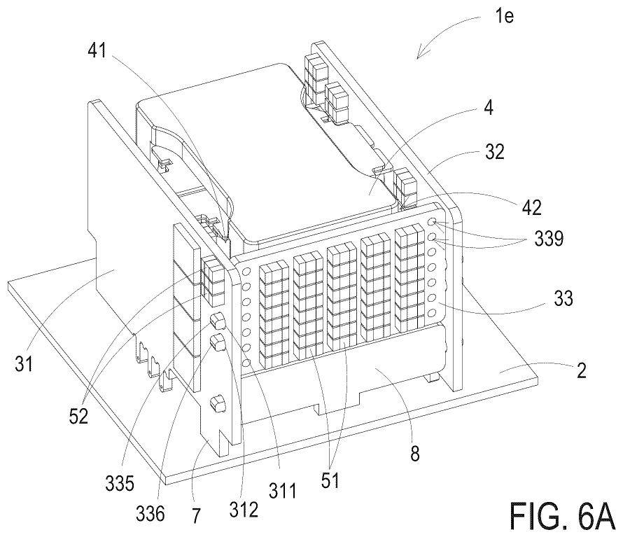

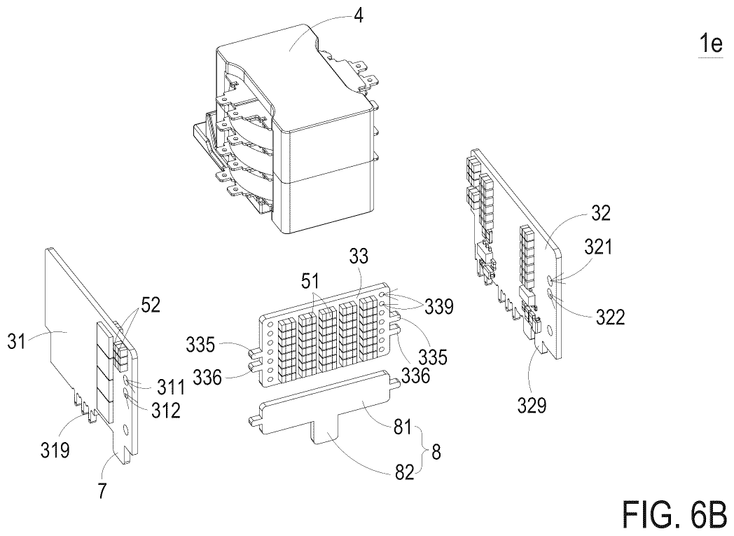

In some embodiments, the positive connection part of the rectifier module is a partial structure of a circuit board. FIG. 6A is a schematic perspective view illustrating the structure of a rectifier module according to a sixth embodiment of the present disclosure. FIG. 6B is a schematic exploded view illustrating the rectifier module shown in FIG. 6A. As mentioned above, the positive connection part 7 of the rectifier module 1c shown in FIGS. 4A and 4B is an additional copper sheet. In this embodiment, the positive connection part 7 of the rectifier module 1e is a partial structure of the first circuit board 31. That is, the positive connection part 7 and the first circuit board 31 are integrally formed as a one-piece structure. In addition, the positive connection part 7 is disposed on a side of the first circuit board 31 adjacent to the mainboard 2. The rectifier module 1e is inserted into the mainboard 2 via the positive connection part 7. In a variant example, the positive connection part 7 is disposed on a side of the second circuit board 32 adjacent to the mainboard 2, and the positive connection part 7 and the second circuit board 32 are integrally formed as a one-piece structure. In another variant example, the rectifier module 1e omits the inductor and utilizes a plurality of output filter capacitors to reduce the output ripple.

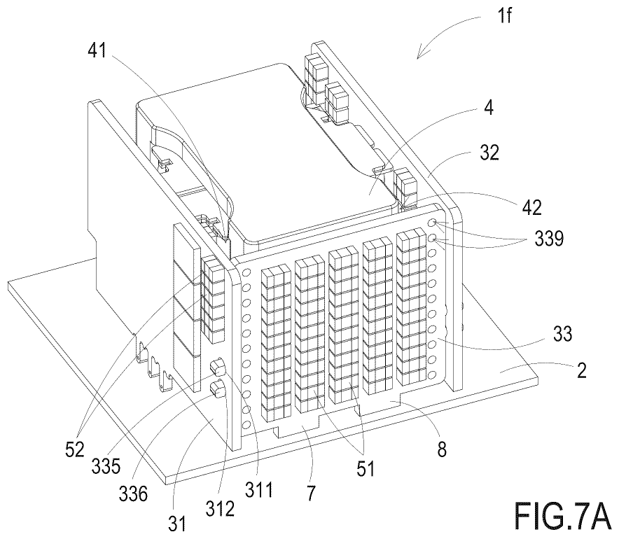

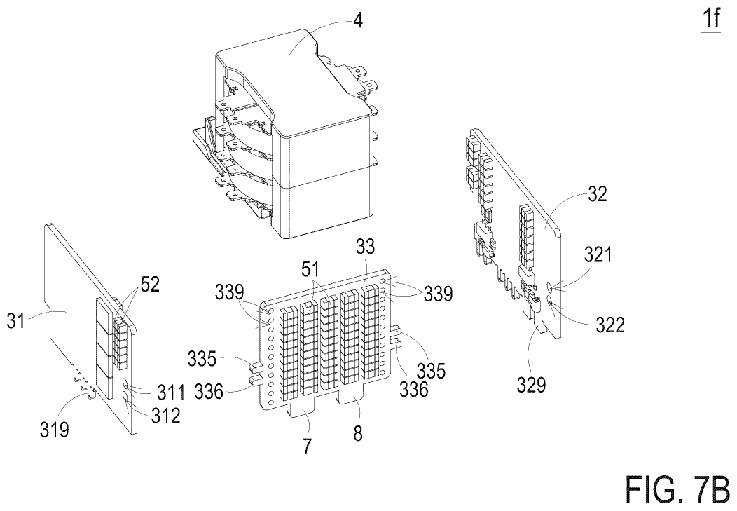

In some embodiments, each of the positive connection part and the negative connection part of the rectifier module is a partial structure of a circuit board. FIG. 7A is a schematic perspective view illustrating the structure of a rectifier module according to a seventh embodiment of the present disclosure. FIG. 7B is a schematic exploded view illustrating the rectifier module shown in FIG. 7A. As mentioned above, the positive connection part 7 of the rectifier module 1 shown in FIGS. 1A and 1B is an additional copper sheet. In the rectifier module 1f of this embodiment, the positive connection part 7 and the negative connection part 8 are both partial structures of the third circuit board 33. In addition, the positive connection part 7 and the negative connection part 8 are integrally formed with the third circuit board 33. The positive connection part 7 and the negative connection part 8 are disposed on the side of the third circuit board 33 adjacent to the mainboard 2. The rectifier module 1f is inserted into the mainboard 2 via the positive connection part 7 and the negative connection part 8. In a variant example, the rectifier module 1f omits the inductor and utilizes a plurality of output filter capacitors to reduce the output ripple. In an embodiment, the plurality of output filter capacitors are electrically connected between the positive connection part 7 and the negative connection part 8.

In the embodiments from the third embodiment to the seventh embodiment, the through-holes are formed in the first circuit board and the second circuit board, and the insertion parts are disposed on the third circuit board. In some variant examples, the through-holes are formed in the third circuit board, and the insertion parts are disposed on the first circuit board and the second circuit board. The installations and structures are similar to those of the second embodiment, and not redundantly described herein.

In the above embodiments, the positive connection part, the negative connection part, the insertion parts and the through-holes are used to electrically connect the first circuit board, the second circuit board and the third circuit board with the positive connection part and the negative connection part. In addition, the positive connection part and the negative connection part are electrically connected to the mainboard. The numbers and positions of the positive connection part, the negative connection part, the insertion parts and the through-holes are not restricted as long as the above purposes can be achieved.

From the above descriptions, the present disclosure provides the rectifier module. The rectifier module includes three circuit boards, i.e., the first circuit board, the second circuit board and the third circuit board. The transformer is arranged between the first circuit board and the second circuit board. The third circuit board is located adjacent to the transformer. In addition, two sides of the third circuit board are respectively connected to the first circuit board and the second circuit board, and a plurality of output filter capacitors may be disposed on the first circuit board and the second circuit board. The output filter capacitors in the rectifier module of the present disclosure can also be disposed on the third circuit board. In other words, the rectifier module of the present disclosure may be provided with a larger number of output filter capacitors. Consequently, the rectifier module achieves enhanced space efficiency, reduced output ripple, and improved dynamic performance through optimized design.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A rectifier module disposed on a mainboard, comprising:
a first circuit board inserted into the mainboard;
a second circuit board inserted into the mainboard and positioned opposite to the first circuit board;
a transformer arranged between the first circuit board and the second circuit board, and connected to the first circuit board and the second circuit board;
a third circuit board located adjacent to the transformer, wherein a first side of the third circuit board is connected to a first side of the first circuit board, and a second side of the third circuit board is connected to a first side of the second circuit board; and
a plurality of output filter capacitors disposed on the third circuit board,
wherein the rectifier module is electrically connected to the mainboard via a positive connection part and a negative connection part.

2. The rectifier module according to claim 1, wherein the positive connection part comprises a first positive connection segment and a second positive connection segment connected to each other, the first circuit board and the second circuit board are both connected to the first positive connection segment, and the first positive connection segment is electrically connected to the mainboard via the second positive connection segment.

3. The rectifier module according to claim 2, wherein the second positive connection segment passes through a hollow portion of a magnetic core, thereby collectively forming an inductor with the magnetic core.

4. The rectifier module according to claim 2, wherein the first circuit board is arranged between the second positive connection segment and the transformer.

5. The rectifier module according to claim 2, wherein both the first circuit board and the second circuit board each comprise at least one first through-hole and at least one second through-hole, and the third circuit board comprises at least two first insertion parts and at least two second insertion parts, wherein the at least two first insertion parts are respectively inserted into the at least one first through-hole of the first circuit board and the at least one first through-hole of the second circuit board, and the at least two second insertion parts are respectively inserted into the at least one second through-hole of the first circuit board and the at least one second through-hole of the second circuit board, wherein a potential of the first insertion part is identical to a potential of a first terminal of the second positive connection segment or a potential of a second terminal of the second positive connection segment, and a potential of the second insertion part is identical to a potential of the negative connection part.

6. The rectifier module according to claim 2, wherein the third circuit board comprises at least two first through-holes and at least two second through-holes, both the first circuit board and the second circuit board each comprise at least one first insertion part and at least one second insertion part, the at least one first insertion part and the at least one second insertion part of the first circuit board are respectively inserted into the corresponding first through-hole and the corresponding second through-hole of the third circuit board, and the at least one first insertion part and the at least one second insertion part of the second circuit board are respectively inserted into the corresponding first through-hole and the corresponding second through-hole of the third circuit board, wherein a potential of the first insertion part in each of the first circuit board and the second circuit board is identical to a potential of a first terminal of the second positive connection segment or a potential of a second terminal of the second positive connection segment, and a potential of the second insertion part in each of the first circuit board and the second circuit board is identical to a potential of the negative connection part.

7. The rectifier module according to claim 1, wherein the negative connection part is integrally formed with the third circuit board, and the negative connection part is disposed on a third side of the third circuit board, wherein the rectifier module is inserted into the mainboard via the negative connection part.

8. The rectifier module according to claim 1, wherein the negative connection part comprises a first negative connection segment and a second negative connection segment connected to each other, the first negative connection segment is connected to the first side of the first circuit board and the first side of the second circuit board, and the rectifier module is inserted into the mainboard via the second negative connection segment of the negative connection part, wherein the third circuit board is arranged between the transformer and the negative connection part, or the negative connection part is arranged between the transformer and the third circuit board, or the negative connection part and the third circuit board are coplanar with each other.

9. The rectifier module according to claim 1, wherein a first gap is defined between the transformer and the first circuit board, a second gap is defined between the transformer and the second circuit board, a first distance is defined between a first portion of the third circuit board and the first circuit board, and a second distance is defined between a second portion of the third circuit board and the second circuit board, wherein a first concave structure is formed between the first portion of the third circuit board and the first circuit board, a second concave structure is formed between the second portion of the third circuit board and the second circuit board, a first airflow channel is jointly defined by the first concave structure and the first gap, and a second airflow channel is jointly defined by the second concave structure and the second gap.

10. The rectifier module according to claim 1, wherein the positive connection part is integrally formed with the first circuit board, the positive connection part is disposed on a third side of the first circuit board, the negative connection part comprises a first negative connection segment and a second negative connection segment connected to each other, the first negative connection segment is connected to the first side of the first circuit board and the first side of the second circuit board, and the rectifier module is inserted into the mainboard via the second negative connection segment of the negative connection part, wherein the third circuit board is arranged between the transformer and the negative connection part, or the negative connection part is arranged between the transformer and the third circuit board, or the negative connection part and the third circuit board are coplanar with each other.

11. The rectifier module according to claim 1, wherein the positive connection part and the negative connection part are integrally formed with the third circuit board, and the positive connection part and the negative connection part are disposed on a third side of the third circuit board, wherein the rectifier module is inserted into the mainboard via the positive connection part and the negative connection part.

12. The rectifier module according to claim 1, wherein the plurality of output filter capacitors on the third circuit board are electrically connected between the positive connection part and the negative connection part.

13. The rectifier module according to claim 1, wherein the third circuit board further comprises a plurality of ventilation holes, wherein a first airflow channel is defined by the combination of the plurality of ventilation holes and a first gap between the first circuit board and the transformer, and a second airflow channel is defined by the combination of the plurality of ventilation holes and a second gap between the second circuit board and the transformer.

14. The rectifier module according to claim 1, wherein the first circuit board comprises at least one first output pin, and the first circuit board is inserted into the mainboard via the at least one first output pin, wherein the second circuit board comprises at least one second output pin, and the second circuit board is inserted into the mainboard via the at least one second output pin.

15. The rectifier module according to claim 1, wherein the rectifier module further comprises at least one rectifier switch disposed on the first circuit board and at least one rectifier switch disposed on the second circuit board.
